(19) United States
(12) Patent Application Publication
(10) Pub. No.: US 2024/0421230 A1
(43) Pub. Date: Dec. 19, 2024

(54) ELECTRONIC DEVICES WITH SUBSTRATES LESS THAN 50 µm THICK AND METHODS OF MANUFACTURE

(71) Applicant: Microchip Technology Incorporated, Chandler, AZ (US)

(72) Inventor: Mankit Lam, Colorado Springs, CO (US)

(73) Assignee: Microchip Technology Incorporated, Chandler, AZ (US)

(21) Appl. No.: 18/533,252

(22) Filed: Dec. 8, 2023

Related U.S. Application Data
(60) Provisional application No. 63/472,953, filed on Jun. 14, 2023.

(51) Int. Cl. H01L 29/786; H01L 21/288; H01L 21/8234; H01L 29/66

(52) U.S. Cl. CPC H01L 29/78642; H01L 21/288; H01L 21/823487; H01L 29/6675

(57) ABSTRACT

A method comprising: molding a structural support coating over the gate pad and source pad at the front side of a wafer; back-side processing the wafer to remove a portion of a silicon layer so that the silicon layer has a post-process thickness, wherein the post-process thickness is less than the pre-process thickness; and removing the structural support coating at the front side of the wafer sufficiently to expose the gate pad and source pad. An electronic device comprising: a silicon layer less than 50 μm thick and defining a back side of the electronic device, a metal layer on the silicon layer, wherein the metal layer defines a front side of the electronic device, wherein the metal layer has a source pad and a gate pad; and a structural support coating between the source pad and the gate pad.

### PRIORITY

This application claims priority to U.S. Provisional Patent Application No. 63/472,953, filed Jun. 14, 2023, the contents of which are hereby incorporated in their entirety.

### TECHNICAL FIELD

The present disclosure relates to field effect transistors, in particular, field effect transistors with substrates less than 50 μm thick so they may have low RDS (on) values and methods to produce field effect transistors with substrates less than 50 μm thick.

### BACKGROUND

Relative to metal oxide field effect transistors, RDS (on) stands for “drain-source on resistance,” or the total resistance between the drain and source in a metal oxide field effect transistor (MOSFET) when the MOSFET is fully “on.” There are two prevailing methods for production of vertical MOSFET devices to attain ultra-thin substrates (>50 μm), which have RDS (on) values (>10 milliohms): (1) grinding a center section of a wafer to an ultra-thin thickness while leaving thicker periphery sections and building the vertical MOSFET on the ultra-thin center section; and (2) adhering a wafer to a support material such as glass, grinding the entire wafer to an ultra-thin thickness, and building the vertical MOSFET on the ultra-thin wafer.

The first method is problematic because the thicker periphery sections of the wafer must be cut away after building the vertical MOSFET(s) and the wafer may break into pieces while being cut. There is also a practical limit to how thin the wafer may be ground without breaking during the grinding process. The thicker periphery sections of the wafer are sacrificed, which is a waste of good silicon. Production costs are high because many steps are used to grind and cut the wafer.

The second method is problematic because the support material must be removed after building the vertical MOSFET(s) and the wafer may break into pieces while the support material is removed.

There is a need for a process for production of vertical MOSFET devices to attain substrates less than 50 μm thick yielding low RDS (on) values that does not tend to break the wafer into pieces.

### SUMMARY OF THE INVENTION

Aspects provide a process for production of vertical MOSFET devices to attain substrates less than 50 μm thick yielding low RDS (on) values that does not tend to break the wafer into pieces.

According to an aspect, there is provided a method comprising: providing a wafer having a front side and a back side, a metal layer having a gate pad and a source pad at the front side, and a silicon layer at the back side wherein the silicon layer has a pre-process thickness; molding a structural support coating over the gate pad and source pad at the front side of the wafer; back-side processing the wafer to remove a portion of the silicon layer so that the silicon layer has a post-process thickness, wherein the post-process thickness is less than the pre-process thickness; and removing the structural support coating at the front side of the wafer sufficiently to expose the gate pad and source pad.

An aspect provides a field effect transistor comprising: a silicon layer less than 50 microns thick, a source pad on the silicon layer; a gate pad on the silicon layer; and a structural support coating on the silicon layer between the source pad and the gate pad.

According to an aspect, there is provided a field effect transistor comprising: a silicon layer less than 50 μm thick and defining a back side of the field effect transistor, a metal layer on the silicon layer, wherein the metal layer defines a front side of the field effect transistor, wherein the metal layer has a source pad and a gate pad; a polymer structural support coating between the source pad and the gate pad; a copper layer built upon the source pad and the gate pad; a drain pad layer on the back side of the silicon layer; and oxidizing inhibiting layers on the front side of the metal layer and the back side of the silicon layer, wherein the field effect transistor has an RDS (on) value less than 100 milliohms.

### BRIEF DESCRIPTION OF THE DRAWINGS

The figures illustrate examples of vertical MOSFET devices attaining substrates less than 50 μm thick yielding low RDS (on) values and methods for manufacturing vertical MOSFET devices attaining low RDS (on) values via ultra-thin substrates.

FIG. 1A shows a cross-sectional, side view of a field effect transistor (FET) wafer having a silicon layer and a metal layer on one side of the silicon layer and defines a front side.

FIG. 1B shows a cross-sectional, side view of the FET wafer of FIG. 1A, wherein a metal is plated on the wafer to build up gate pads and source pads on corresponding portions of the metal layer.

FIG. 1C shows a cross-sectional, side view of the FET wafer of FIG. 1B, wherein the FET wafer is overmolded with a structural support coating.

FIG. 1D shows a cross-sectional, side view of the FET wafer of FIG. 1C, wherein the silicon layer has been ground to a thickness less than 50 μm.

FIG. 1E shows a cross-sectional, side view of the FET wafer of FIG. 1D, wherein a drain pad layer is applied to the silicon layer.

FIG. 1F shows a cross-sectional, side view of the FET wafer of FIG. 1E, wherein the front side of the FET wafer has been ground to remove a portion of the structural support coating, whereby the gate pads and source pads are exposed or revealed.

FIG. 1G shows a cross-sectional, side view of the FET wafer of FIG. 1F, wherein plating layers are added to the front and back sides of the FET wafer.

FIG. 1H shows a cross-sectional, side view of the FET wafer of FIG. 1G, wherein the FET wafer has been singulated or cut into individual chips.

FIG. 2 shows a flowchart for manufacturing vertical MOSFET devices with substrates less than 50 μm thick yielding low RDS (on) values.

FIG. 3 shows a cross-sectional side view of a microchip package comprising MOSFET devices substrates less than 50 μm thick yielding low RDS (on) values.

FIGS. 4A through 4F show a MOSFET device being produced from a wafer. FIG. 4A is a top view showing a source pad, a gate pad and a die top passivation layer.

FIG. 4B is a cross-sectional, side view of the MOSFET device shown in FIG. 4A showing the silicon layer is full thickness.

FIG. 4C is a cross-sectional, side view of the MOSFET device shown in FIGS. 4A and 4B showing a copper plating on the front side of the wafer forming a source contact on the source pad and a gate contact on the gate pad.

FIG. 4D is a cross-sectional, side view of the MOSFET device shown in FIGS. 4A through 4C showing a structural support coating over the passivation layer, the source pad, the source contact, the gate pad, and the gate contact.

FIG. 4E is a cross-sectional, side view of the MOSFET device shown in FIGS. 4A through 4D and shows the silicon layer has been ground to a very thin thickness to attain ultra low RDS (on) values.

FIG. 4F is a cross-sectional, side view of the MOSFET device shown in FIGS. 4A through 4E and shows the structural support coating has been ground away until the portions of it over the source contact and the gate contact are removed.

The reference number for any illustrated element that appears in multiple different figures has the same meaning across the multiple figures, and the mention or discussion herein of any illustrated element in the context of any particular figure also applies to each other figure, if any, in which that same illustrated element is shown.

### DESCRIPTION

According to an aspect, there is provided a process for production of vertical MOSFET devices to attain substrates less than 50 μm thick yielding low RDS (on) values that does not tend to break the wafer into pieces. MOSFET devices with substrates less than 50 μm thick may have RDS (on) values less than 10 milliohms.

By over-molding the MOSFET wafer with a structural support coating prior to a grinding process, the structural support coating provides mechanical support to allow the MOSFET wafer to be ground to an ultra-thin thickness. In some aspects, the MOSFET wafer may be ground to less than 50 μm thickness, and even down to 1 μm thickness. The ultra-thin MOSFET wafer may be plated with a Cu layer to enhance electrical and thermal conductivity.

The wafer thinning process (grinding) may comprise several stages: course grinding, fine grinding, and stress relief by dry polishing or wet polishing.

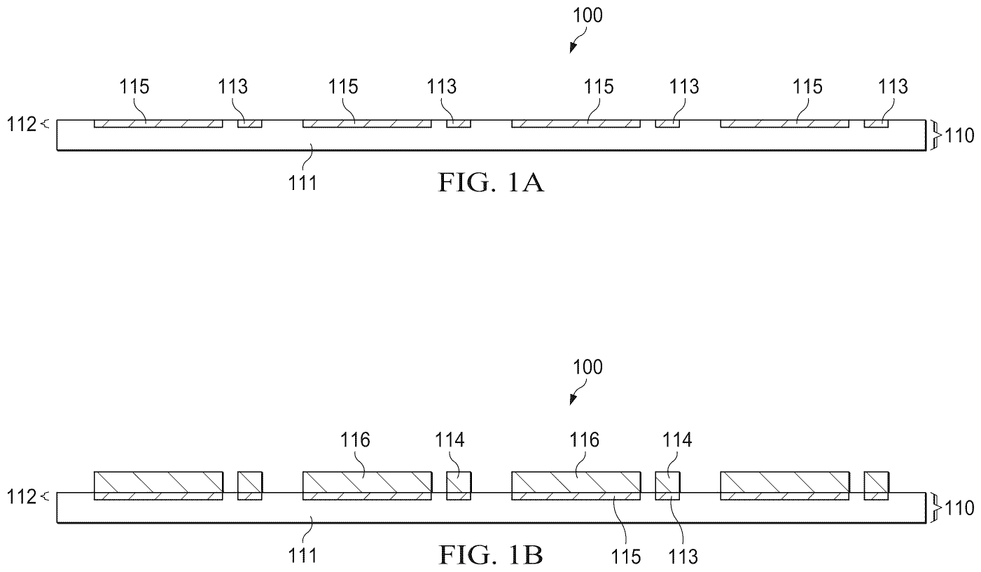

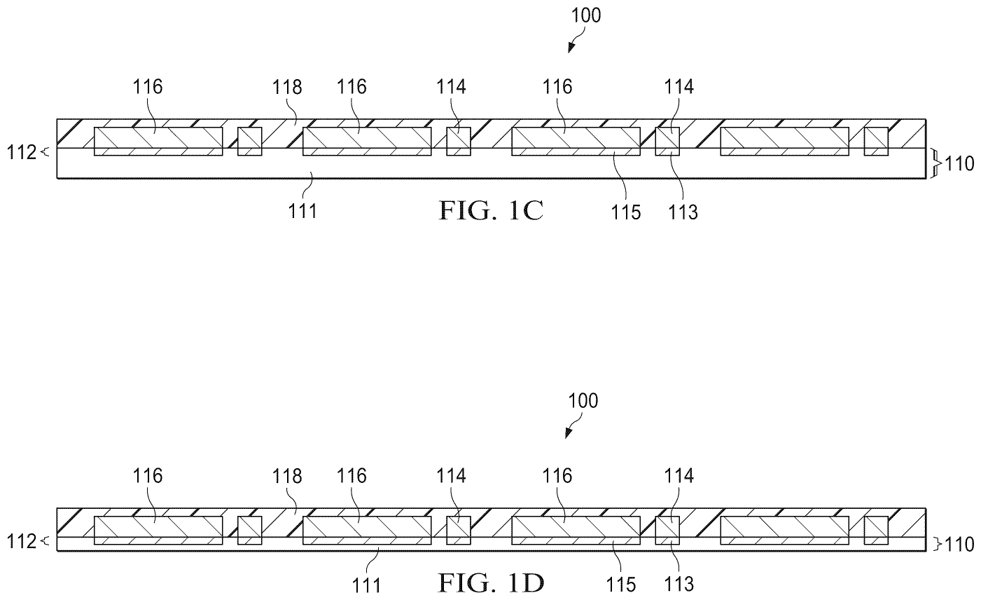

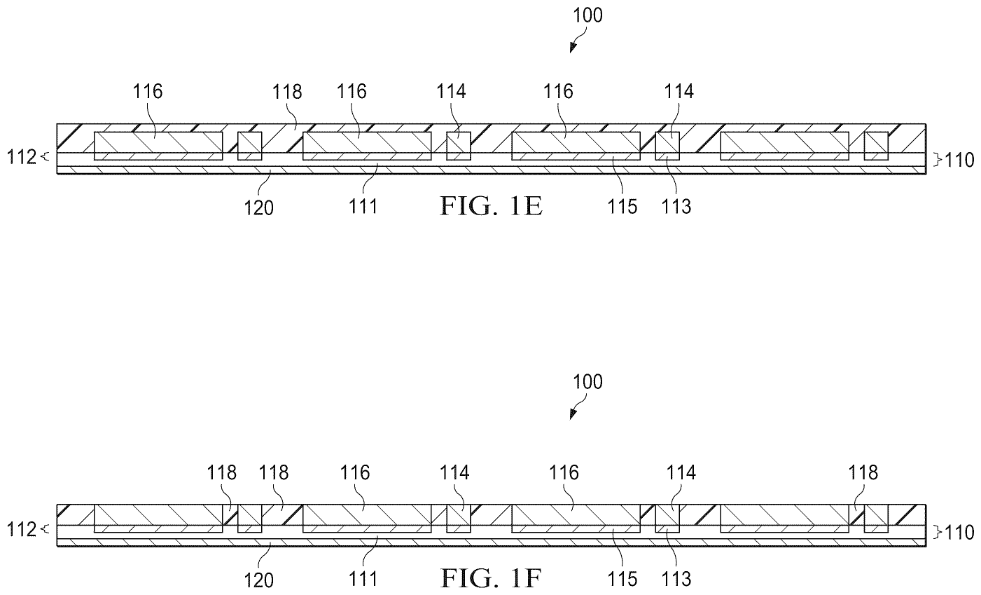

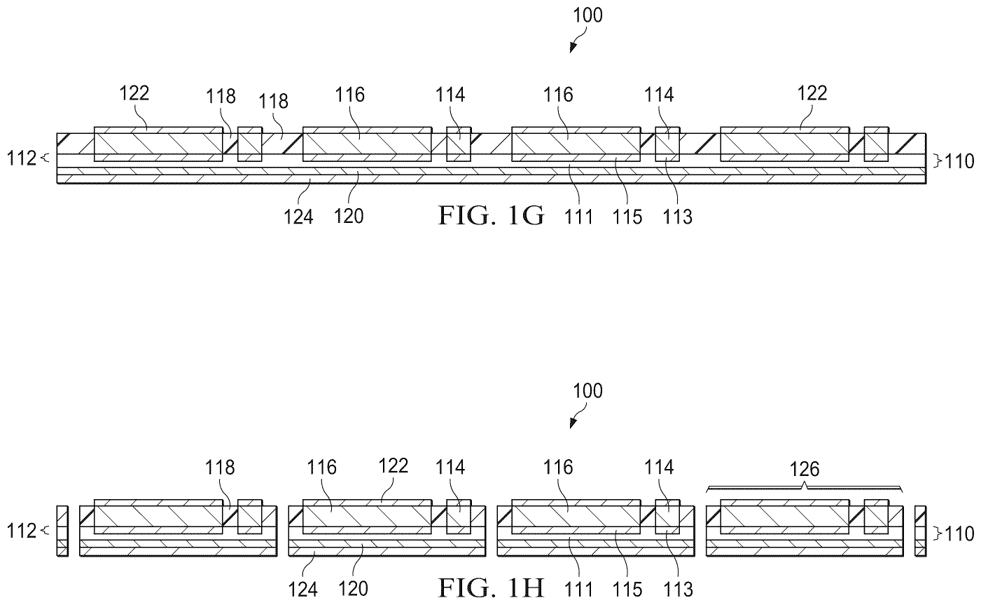

FIG. 1A shows a cross-sectional, side view of a field effect transistor (FET) wafer. The FET wafer 100 has a silicon layer 110 and a metal layer 112. The metal layer 112 defines a front side. The wafer 100 may be an 8-inch, full thickness wafer (thickness between 0.4 mm (400 microns) and 0.8 mm (800 microns)). A metal layer 112 is on one side of the silicon layer 110, wherein the metal may be aluminum or any other metal. The metal layer 112 may define gate pads 113 and source pads 115. A full thickness FET wafer 100 including the silicon layer 110 and the metal layer 112 may be greater than or equal to about 725 microns thick. FIG. 1A shows a raw die with which one may start the process. A doped region of the silicon layer 110, i.e. the transistor source may be under the source pads 115. An insulation layer may be under the gate pads 113 (there may be a layer of polysilicon below the gate pad and above the insulation layer). The gate pad 113 and insulation layer may act as the gate of the transistor.

FIG. 1B shows a cross-sectional, side view of the FET wafer 100 of FIG. 1A. A metal is plated on the wafer 110 to build up gate contacts 114 and source contacts 116 on corresponding gate pads 113 and source pads 115 of the metal layer 112. The metal of the gate contacts 114 and source contacts 116 may be Cu or any other metal. The result may be copper on aluminum. The gate contacts 114 and source contacts 116 may be about 125 microns, so that the entire FET wafer 100 as shown in FIG. 1B may be 850 microns.

FIG. 1C shows a cross-sectional, side view of the FET wafer 100 of FIG. 1B. The FET wafer 100 is overmolded with a structural support coating 118, wherein the structural support coating 118 may be a polymer. The structural support coating 118 may be an epoxy mold compound (EMC) and may be applied using a compression molding process. The structural support coating 118 may be about 75 microns, gate contacts 114 and source contacts 116 may be about 125 microns, and the silicon layer may be about 725 microns, so that the entire FET wafer 100 as shown in FIG. 1C may be 925 microns.

FIG. 1D shows a cross-sectional, side view of the FET wafer of FIG. 1C. The silicon layer 110 may be ground to an ultra-thin thickness (i.e., less than 50 microns, in one example between 2 microns and 25 microns). Because the gate and source pads 114 and 116 and the structural support coating 118 provide structural rigidity and support, a significant portion of the silicon layer 110 may be ground away. In theory, from the perspective of structural rigidity and support provided by the structural support coating 118, the silicon layer 110 may be ground to 1 μm thick), but some silicon should remain to provide for a “drain.” Drains 111 may be in the remaining silicon layer 110. In an example where the silicon layer 110 is ground to a thickness of less than 50 microns, the gate contacts 114 and source contacts 116 may be about 125 microns, and the structural support coating 118 is about 75 microns, then the entire FET wafer 100 as shown in FIG. 1D may be 250 microns.

FIG. 1E shows a cross-sectional, side view of the FET wafer 100 of FIGURE ID. Depending on the thickness of the silicon layer 110 after grinding, a drain pad layer 120 may be applied to the silicon layer 110. The drain pad layer 120 may be Ti—Cu or other metal and may be applied by a sputter process to the backside of the FET wafer 100. In an example where the drain pad layer 120 is about 2 microns thick, the silicon layer 110 is about 50 microns, the gate contacts 114 and source contacts 116 is about 125 microns, and the structural support coating 118 is about 75 microns, that the entire FET wafer 100 as shown in FIG. 1E may be 252 microns.

FIG. 1F shows a cross-sectional, side view of the FET wafer 100 of FIG. 1E. The front side of the FET wafer 100 has been ground to remove a portion of the structural support coating 118, whereby the gate contacts 114 and source contacts 116 may be exposed or revealed. This may allow other components to be soldered to the gate contacts 114 and source contacts 116. While the structural support coating 118 (see FIG. 1E) is removed from the front sides of the gate contacts 114 and source contacts 116, material of structural support coating 118 may remain between the gate contacts 114 and source contacts 116 and have the same thickness as the gate contacts 114 and source contacts 116. After grinding, a surface of the structural support coating 118, a surface of the source contact 116, and a surface of the gate contact 114 may be coplanar. In an example, the drain pad layer 120 may be about 2 microns thick, the silicon layer 110 is about 50 microns, and the gate contacts 114 and source contacts 116 may be about 125 microns, so that the entire FET wafer 100 as shown in FIG. 1F may be 177 microns in thickness.

FIG. 1G shows a cross-sectional, side view of the FET wafer of FIG. 1F. A plating layer 122 may be added to the front side of the FET wafer 100 and another plating layer 124 may be added to the back side of the FET wafer 100. These plating layers may inhibit the Cu from oxidizing and may provide common PCB layers for solder and bonding. The plating layers may be electroless nickel immersion gold (ENIG) plating or electroless nickel palladium gold (ENEPIG) plating. The plating of the front and back sides of the wafer may be with oxidizing inhibiting layers. In an example, the plating layers 122 and 124 may be about 2 microns each, the drain pad layer 120 may be about 2 microns thick, the silicon layer 110 may be about 50 microns, and the gate contacts 114 and source contacts 116 may be about 125 microns, so that the entire FET wafer 100 as shown in FIG. 1G may be 181 microns.

FIG. 1H shows a cross-sectional, side view of the FET wafer 100 of FIG. 1G. The FET wafer 100 may be singulated or cut into individual chips 126.

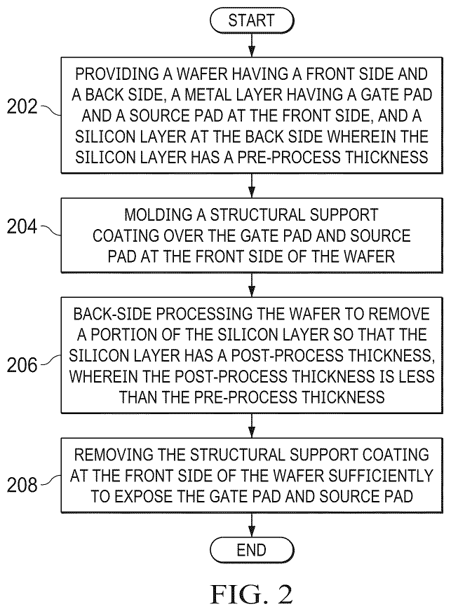

FIG. 2 shows a flowchart for manufacturing vertical MOSFET devices with substrates less than 50 μm thick yielding low RDS (on) values. A wafer is provided 202 having a front side and a back side, a metal layer having a gate pad and a source pad at the front side, and a silicon layer at the back side wherein the silicon layer has a pre-process thickness. See FIG. 1A. A structural support coating is molded 204 over the gate pad and source pad at the front side of the wafer. See FIG. 1C. The wafer is back-side processed 206 to remove a portion of the silicon layer so that the silicon layer has a post-process thickness, wherein the post-process thickness is less than the pre-process thickness. See FIG. 1D. The structural support coating is removed 208 at the front side of the wafer sufficiently to expose the gate pad and source pad. See FIG. 1F.

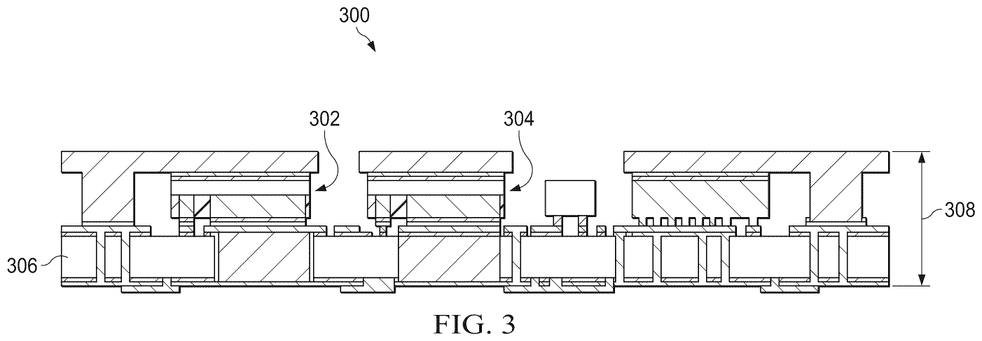

FIG. 3 shows a cross-sectional side view of a microchip package 300 comprising two MOSFET devices 302 and 304. The MOSFET devices 302 and 304 are mounted on a printed circuit board 306. Because the MOSFET devices 302 and 304 have substrates less than 50 μm thick, the overall thickness 308 of the microchip package 300 is small.

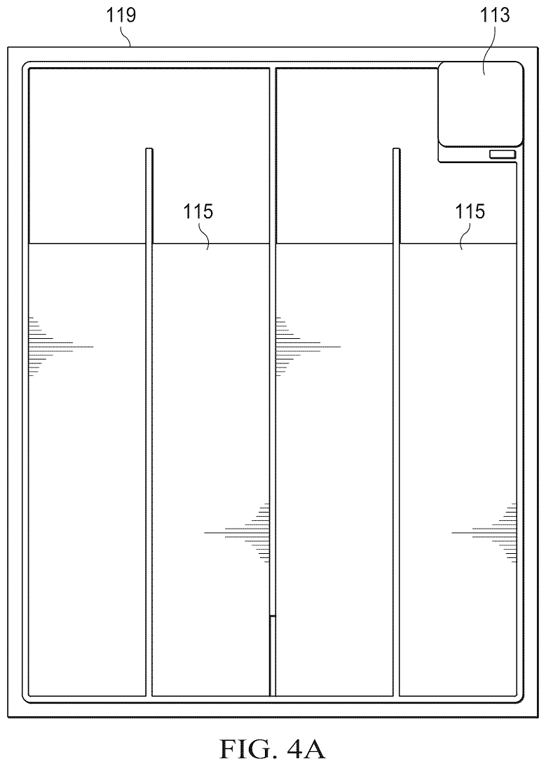

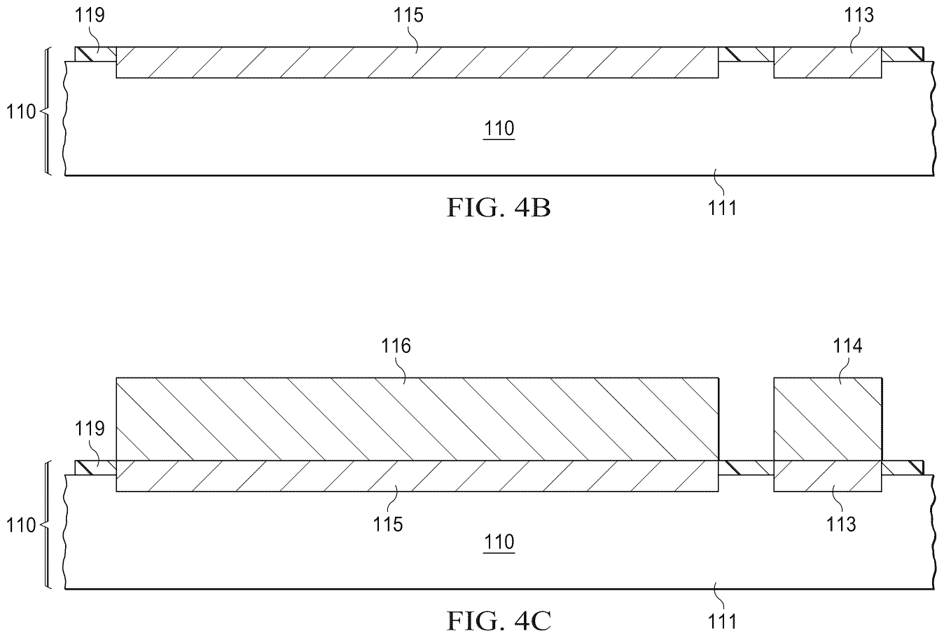

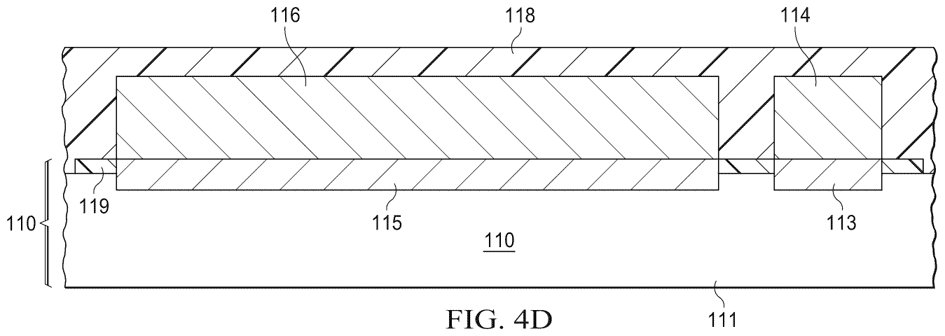

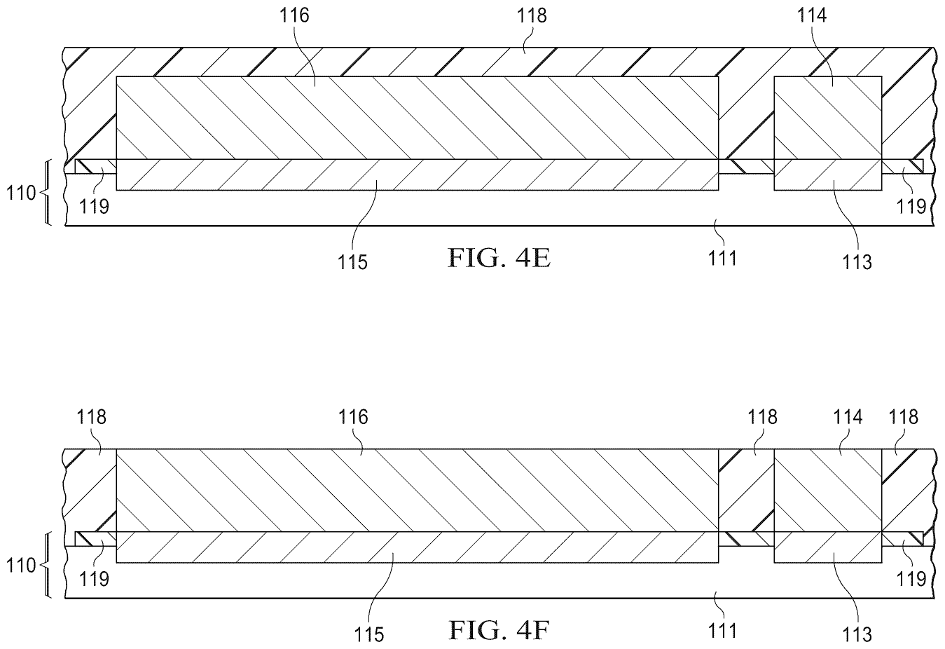

FIGS. 4A through 4F show a MOSFET device being produced from a wafer. FIG. 4A is a top view showing a source pad 115, a gate pad 113 and a die top passivation layer 119.

FIG. 4B is a cross-sectional, side view of the MOSFET device shown in FIG. 4A. FIG. 4B shows the silicon layer 110 is full thickness (about 723 μm), which is a typical fab-out thickness. Top aluminum bond pads are at the front side of the silicon layer 110 forming a source pad 115 and a gate pad 113. A drain 111 is in the silicon layer 110.

FIG. 4C is a cross-sectional, side view of the MOSFET device shown in FIGS. 4A and 4B. FIG. 4C shows a copper plating on the front side of the wafer forming a source contact 116 on the source pad 115 and a gate contact 114 on the gate pad 113.

FIG. 4D is a cross-sectional, side view of the MOSFET device shown in FIGS. 4A through 4C. FIG. 4D shows a structural support coating 118 over the passivation layer 119, the source pad 115, the source contact 116, the gate pad 113, and the gate contact 114. The silicon layer 110 is full thickness (about 723 μm).

FIG. 4E is a cross-sectional, side view of the MOSFET device shown in FIGS. 4A through 4D. FIG. 4E shows a structural support coating 118 over the passivation layer 119, the source pad 115, the source contact 116, the gate pad 113, and the gate contact 114. The silicon layer 110 has been ground to a very thin thickness (less than or equal to 50 μm and as thin as 1 μm) to attain ultra low RDS (on) values less than 10 milliohms. The drain 111 is in the thin thickness silicon layer 110.

FIG. 4F is a cross-sectional, side view of the MOSFET device shown in FIGS. 4A through 4E. FIG. 4F shows the structural support coating 118 has been ground away until the portions of it over the source contact 116 and the gate contact 114 are removed. However, the structural support coating 118 adjacent the source contact 116 and the gate contact 114 remains. In particular, the structural support coating 118 between the source contact 116 and the gate contact 114 remains. The drain 111 is in the thin thickness silicon layer 110.

Although examples have been described above, other variations and examples may be made from this disclosure without departing from the spirit and scope of these disclosed examples.

1. A method comprising:
providing a wafer having a front side and a back side, a metal layer having a gate pad and a source pad at the front side, and a silicon layer at the back side wherein the silicon layer has a pre-process thickness;
molding a structural support coating over the gate pad and source pad at the front side of the wafer;
back-side processing the wafer to remove a portion of the silicon layer so that the silicon layer has a post-process thickness, wherein the post-process thickness is less than the pre-process thickness; and
removing the structural support coating at the front side of the wafer sufficiently to expose the gate pad and source pad.

2. The method as in claim 1, wherein the pre-process thickness of the silicon layer is greater than or equal to 700 μm.

3. The method as in claim 1, wherein the post-process thickness of the silicon layer is less than or equal to 50 μm.

4. The method as in claim 1, wherein the structural support coating comprises polymer.

5. The method as in claim 1, wherein the back-side processing comprises grinding and the removing of the structural support coating comprising grinding.

6. The method as in claim 1, comprising plating the front side of the wafer to build up the gate pad and source pad.

7. The method as in claim 6, wherein the plating comprises plating with copper (Cu).

8. The method as in claim 1, comprising adding a drain pad layer on the back side of the wafer.

9. The method as in claim 1, comprising plating the front and back sides of the wafer with oxidizing inhibiting layers.

10. The method as in claim 1, comprising singulating the wafer to form individual chips.

11. An electronic device comprising:
a silicon layer less than 50 μm thick and defining a back side of the electronic device,
a metal layer on the silicon layer, wherein the metal layer defines a front side of the electronic device, wherein the metal layer has a source pad and a gate pad; and
a structural support coating on the front side between the source pad and the gate pad.

12. The electronic device as in claim 11, wherein the structural support coating comprises polymer.

13. The electronic device as in claim 11, wherein a surface of the structural support coating, a surface of the source pad, and a surface of the gate pad are coplanar.

14. The electronic device as in claim 11, comprising a copper (Cu) layer on the gate pad and source pad on the front side of the wafer.

15. The electronic device as in claim 11, wherein the electronic device has an RDS (on) value less than 10 milliohms.

16. The electronic device as in claim 11, comprising a drain pad layer on the back side of the silicon layer.

17. The electronic device as in claim 11, comprising oxidizing inhibiting layers on the front side of the metal layer and the back side of the silicon layer.

18. The electronic device as in claim 17, wherein the oxidizing inhibiting layers comprise an electroless nickel immersion gold plating.

19. A field effect transistor comprising:
a silicon layer less than 50 μm thick and defining a back side of the field effect transistor,
a metal layer on the silicon layer, wherein the metal layer defines a front side of the field effect transistor, wherein the metal layer has a source pad and a gate pad;
a polymer coating on the front side between the source pad and the gate pad;
a copper layer on the source pad and the gate pad;
a drain pad layer on the back side of the silicon layer; and
oxidizing inhibiting layers on the front side of the metal layer and the back side of the silicon layer,
wherein the field effect transistor has an RDS (on) value less than 10 milliohms.

20. The field effect transistor as in claim 19, wherein a surface of the structural support coating, a surface of the source pad, and a surface of the gate pad are coplanar.
